(19) United States
(12) Patent Application Publication
(10) Pub. No.: US 2024/0411953 A1
(43) Pub. Date: Dec. 12, 2024

(54) REPRESENTATIVE CRUDE OIL ASPHALTENE DEPOSITION SIMULATION IN A MICRO-REACTOR USING MULTI-FACTOR EXPERIMENTAL DESIGN

(71) Applicant: ChampionX LLC, Sugar Land, TX (US)

(72) Inventor: Christopher Alexander Russell, Sugar Land, TX (US)

(21) Appl. No.: 18/676,977

(22) Filed: May 29, 2024

Related U.S. Application Data
(60) Provisional application No. 63/507,234, filed on Jun. 9, 2023.

(51) Int. Cl. G06F 30/20

(52) U.S. Cl. CPC G06F 30/20

(57) ABSTRACT

Multi-factor experimental design on a laboratory-scale is utilized to obtain a multiple-variable equation containing multiple variables for calculating a parameter using laboratory-measured data. The multiple-variable equation is set equal to a target field value for the parameter, and experiment values for the variables in the multiple-variable equation are then determined based on setting the multiple-variable equation equal to the target field value for the parameter. A laboratory confirmation experiment is then conducted under conditions that are at the experiment values for the variables to obtain a simulated field result value for the parameter.

### CROSS-REFERENCE TO RELATED APPLICATION

This application is a non-provisional patent application claiming the benefit of, and priority to, U.S. Provisional Patent Application No. 63/507,234, filed Jun. 9, 2023, which is incorporated by reference herein in its entirety.

### FIELD OF THE DISCLOSURE

The present disclosure generally relates to multi-factor experimental design, and more particularly to multi-factor experimental design for laboratory-scale crude oil asphaltene deposition experiments.

### BACKGROUND

Chemical compounds that function as asphaltene control chemicals can be tested on a crude oil from a particular wellsite in a laboratory setting. Laboratory-scale asphaltene deposition experiments are usually conducted with single-factor experimental designs. In single-factor experimental designs, all variables in a series of experiments are held constant except for a single variable that is adjusted in value among the series of experiments, to determine how changes in the single variable affect asphaltene deposition. The changes in asphaltene deposition relative to values of the single variable can be used to identify whether a variable correlates to asphaltene deposition, and in some cases where correlation is present, an optimum value for the variable. When testing for multiple variables is desired, the single-factor experimental design involves multiple subsequent series of experiments for each additional variable. The number of experiments needed in a single-factor experimental design is large and burdensome when determining the optimal value for multiple variables. In an example of 10 experiments for each of three variables, 30 experiments can be conducted to determine if any of the three variables has any correlation to, and optimum value for, asphaltene deposition. Moreover, single-factor experimental design do not account for the effect of variables upon one another.

There is a need for a technique that can test multiple variables in a laboratory setting and determine the relationship of multiple variables to a test parameter without the large number of tests required in single-factor experimental design.

### SUMMARY

Disclosed is a method that can include: obtaining a multiple-variable equation containing a plurality of variables for calculating a parameter using laboratory-measured data; setting the multiple-variable equation equal to a target field value for the parameter; determining experiment values for the plurality of variables in the multiple-variable equation based on setting the multiple-variable equation equal to the target field value for the parameter; and conducting a laboratory confirmation experiment under conditions that are at the experiment values for the plurality of variables to obtain a simulated field result value for the parameter.

Disclosed is a computer having at least one processor and at least one memory containing instructions, that when executed by the at least one processor, cause the computer to: generate a multiple-variable equation containing a plurality of variables for calculating a parameter using laboratory-measured data; receive a target field value for the parameter via a first user input to the computer; set the multiple-variable equation equal to the target field value for the parameter; and determine experiment values for the plurality of variables in the multiple-variable equation based on setting the multiple-variable equation equal to the target field value for the parameter.

Disclosed is an apparatus configured to operate a laboratory confirmation experiment under conditions that are at experiment values for a plurality of variables to obtain a simulated field result value for a parameter that can be measured from the laboratory confirmation experiment, wherein multiple-variable experimental design is used to determine a multiple-variable equation, wherein the experiment values are determined by setting the multiple-variable equation equal to a target field value.

Disclosed is a system having the computer and the apparatus.

Other technical features may be readily apparent to one skilled in the art from the following figures, descriptions and claims.

### BRIEF DESCRIPTION OF THE DRAWINGS

For a more complete understanding of this disclosure, reference is now made to the following description, taken in conjunction with the accompanying drawings, in which:

FIG. 1 illustrates a flowchart of a method disclosed herein.

FIG. 2 illustrates a flowchart of an embodiment of the first step in the method of FIG. 1

FIG. 3 illustrates a flowchart of additional steps in the disclosed method.

FIG. 4 illustrates a flowchart of additional steps in the disclosed method.

FIG. 5 illustrates a schematic diagram of an apparatus used in the examples.

FIG. 6 illustrates a cross-sectional view of the micro-reactor in the apparatus of FIG. 5.

FIG. 7 is a flocculation point analysis graph.

FIG. 8 is a bar graph of asphaltene deposit mass for several performance experiments.

### DETAILED DESCRIPTION

The ability to have laboratory-scale experiments for asphaltene deposition accurately reflect the results that are obtained in the field is a challenge. In the context of asphaltene control in a crude oil, multiple variables can ultimately affect how asphaltene control chemicals perform in the field, including temperature, contact time, shear stress, and precipitant concentration (e.g., heptane concentration). Traditional methods of laboratory testing, in general, include conducting a series of experiments by varying one variable over the series of experiments while keeping all other variables constant, in order to determine any relationship of the variable with a parameter. For parameters that may have a relationship with multiple variables, multiple series of experiments are conducted whereby a first variable is varied in a first series of experiments, a second variable is varied in a second series of experiments, and so on. This is sometime referred to as single-factor experimental design. In single-factor experimental design, there is a set of experiments for each variable where each variable is varied across multiple tests while all other variables are held constant. In the context of asphaltene deposition in a crude oil, a first series of experiments can be conducted to determine a relationship for temperature on asphaltene deposition, then a second series of experiments can be conducted to determine a relationship for duration of experiment (contact time) on asphaltene deposition, and then a subsequent series of experiments is conducted for each additional variable to be investigated.

Disclosed herein are laboratory-scale testing techniques that utilize multiple-variable experimental design. The laboratory-scale testing techniques have a rapid test time compared to single-variable experimental design, allows a selection of laboratory experiments to probe the statistical significance of variables, and allows response to target field values. Moreover, with the disclosed laboratory-scale testing techniques it is possible to target field values that are measured or determined from different types of commercial-scale equipment than the apparatus used in the laboratory experiments. Further, the laboratory-scale testing techniques can be applied to any procedure of laboratory experimentation.

The laboratory-scale testing techniques are disclosed in the context of asphaltene deposition in crude oil; however, it is contemplated that the techniques can be utilized in other applications where laboratory-scale experiments are used to predict performance in the field (in commercial application, at commercial scale), regardless of the type of industry.

“Laboratory” and “laboratory-scale,” when used to describe a type of data, application, procedure, experiment, apparatus, or when otherwise used to describe as aspect of this disclosure, are terms that refer to a stage of scientific research and investigation that is conducted at a scale that is smaller than a present or future commercial-scale implementation of a technology. The research and investigation can involve experiments conducted by personnel using an apparatus that is configured to operate such that a parameter can be measured.

“Field,” “commercial,” or “commercial scale,” when used to describe a type of data, application, procedure, experiment, apparatus, or when otherwise used to describe as aspect of this disclosure, are terms that refer to a present or future commercial-scale implementation of a technology. The scale of a “field,” “commercial,” or “commercial scale” implementation is larger than the scale of a “laboratory” and “laboratory-scale” implementation.

“Experiment” as used herein refers to a procedure or test that is performed using an apparatus, whereby a parameter can be measured during the procedure or from a product/result of the procedure.

“Conducting” when used with reference to any experiment discussed herein can be used interchangeably with “performing.”

“Parameter” as used herein refers to any characteristic, property, condition, or otherwise that can be measured to ascertain a performance metric associated with the experiment.

“Multi-variable equation,” “multiple-variable equation,” “multi-factor equation,” and “multiple-factor equation” are terms that refer to an equation having multiple variables, e.g., xA+yB=C or xA+yB+zC=D. In aspects, the multiple variables are located only on one side of the equation, such as xA+yB=C. In other aspects, the multiple variables can be located on both sides of the equation, such as xA+yB=zC+D. The form of the equation and mathematical functions that can be contained in the equation are not limited by this disclosure.

“Multi-variable experimental design,” “multiple-variable experimental design,” “muti-factor experimental design,” and “multiple-factor experimental design” can be used interchangeably.

“Laboratory experiment,” “laboratory confirmation experiment,” and “performance experiment” are all laboratory experiments. The different names for these experiments indicate performance of the experiments at different times, where when performed in the method disclosed herein, laboratory experiments are performed before laboratory confirmation experiments, and laboratory confirmation experiments are performed before performance experiments. Similarities and differences among these differently named experiments are described in more detail herein.

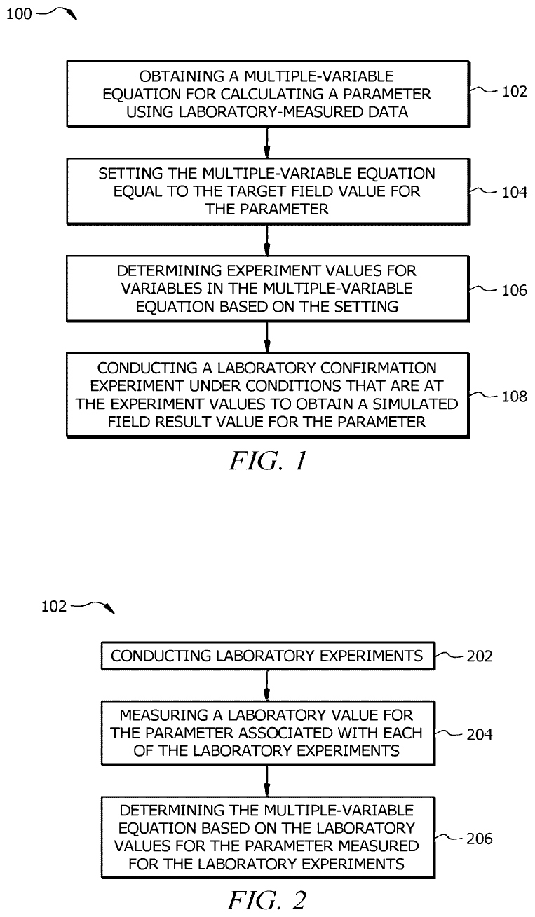

FIG. 1 illustrates a flowchart of a method 100 disclosed herein.

The method 100 in FIG. 1 begins with step 102. In step 102, the method 100 includes obtaining a multiple-variable equation containing multiple variables for calculating a parameter using laboratory-measured data. A nonlimiting example of a multiple-variable equation may be:

$$xA + yB + zC = P \qquad ( 1 )$$

where x, y, and c are numbers; A, B, and C are values for three variables that can be selected for laboratory experiments; and P is a value for a parameter obtained from the laboratory experiments.

The multiple-variable equation is obtained because experiments are conducted under a multi-factor experimental design. The number of variables that can be used in a multiple-variable equation is not limited by this disclosure. In aspects, the number of variables in a multiple-variable equation can be in a range of from 2 to 15 variables; alternatively, 2 to 10 variables; alternatively, 2 to 5 variables. The parameter can be any parameter that is measurable with experiments conducted on a laboratory-scale. The laboratory-measured data can include the numerical values for the variables that can be measured and/or recorded from one or more experiments. The laboratory-measured data can also include the numerical values for the parameter that can be measured and/or recorded from one or more experiments.

In aspects where the parameter is asphaltene deposition in a crude oil and the experiment is performed in an apparatus (e.g., a micro-reactor), the variables can be two or more of a temperature of the apparatus, a duration of experiment, a heptane concentration in the apparatus, a mixing rate in the apparatus (which is related to wall shear stress); the parameter is asphaltene deposition; and the laboratory-measured data are the numerical values for the variables and the numerical values for the asphaltene deposition.

The multiple-variable equation can be obtained by any technique known in the art with the aid of this disclosure. One technique is described in FIG. 2, and an example in the context of asphaltene deposition measurement is described in the examples.

The method 100 then proceeds to step 104. At step 104, the method 100 can include setting the multiple-variable equation equal to a target field value for the parameter. The equation (1) above is changed to:

$$xA + yB + zC = Target Field Value \qquad ( 2 )$$

The target field value for the parameter is a value that is not obtained through previous laboratory experiments; instead, the target field value is obtained from field, or commercial-scale implementations of a product or process. The disclosed method 100 differs from other techniques, in that, the multiple-variable equation is set to a value for the parameter, referred to herein as the target field value, where the target field value is obtained or derived from commercial-scale implementation of a product or process (as opposed to a laboratory-scale implementation).

In aspects, the target field value can be the same as a known field value; alternatively, the target field value can be an average of known field values; alternatively, the target field value can be a value that falls within a range of known field values; alternatively, the target field value can be a value that is indirectly obtained (e.g., via estimation, calculation, derivation, inference, extrapolation, or combinations thereof) from known condition measurements in a commercial-scale process or product. The target field value and known field value refer to values for a parameter that are obtained and known, respectively, from a commercial scale and/or commercial implementation or application of a technology.

In the context of asphaltene deposition in a crude oil, the target field value can be a known field value or average of known field values of asphaltene deposition at a well site, from a crude oil that flows through production equipment (e.g., production valving, production tubing, pumps, separators, or combinations thereof). In some cases, a target field value for asphaltene deposition may be calculated or derived from other known parameters and/or conditions at a wellsite, such as an observation that 1) a known wt % of available asphaltenes in a crude oil deposit onto an equipment surface that comes into contact with the crude oil, and 2) the crude oil at a particular point in production equipment has a known wt % asphaltenes present based on a total weight of the crude oil. For example, a target field value for asphaltene deposition can be calculated with information that 1) 8 wt % to 10 wt % of available asphaltenes in a crude oil deposit onto an equipment surface that comes into contact with the crude oil, and 2) the crude oil at a particular point in production equipment has 40 wt % asphaltenes present based on a total weight of the crude oil.

The method 100 then proceeds to step 106. At step 106, the method 100 can include determining experiment values for the variables in the multiple-variable equation based on setting the multiple-variable equation equal to the target field value for the parameter. In aspects, step 106 is performed by a multiple-variable experimental design computer. In some aspects, this step 106 reverses the analysis that was performed to obtain the multiple-variable equation. That is, in some aspects the multiple-variable equation is obtained by conducting laboratory experiments under conditions for the variables that were previously selected under multiple-variable experimental design and that are then performed in the laboratory experiments, to obtain values for the parameter. In step 106, instead of conducting experiments to obtain values for the parameter, the target field value for the parameter is set equal to the multiple-variable equation, and experiment values for the variables in the multiple-variable equation are calculated that cause the equation to equal the target field value for the parameter. The term “experiment values” is used herein to differentiate the values for the variables that are obtained in step 106 versus values for the variables obtained in another step of the method 100.

The method 100 then proceeds to step 108. At step 108, the method 100 can include conducting a laboratory confirmation experiment under conditions that are at the experiment values for the variables, to obtain a simulated field result value for the parameter. The laboratory confirmation experiment is conducted under a procedure that can be followed for all laboratory-scale experiments conducted herein. In aspects where the parameter is asphaltene disposition, the laboratory confirmation experiment in step 108 is conducted without presence of an asphaltene control chemical.

Significantly, the amount of time to perform method 100 in FIG. 1 using multi-variable experimental design to obtain the multiple-variable equation in step 102 is a fraction of the amount of time it takes to obtain a multiple-variable equation with single-variable experimental design. Also significant about the method 100 in FIG. 1 is that steps 104, 106, and 108 utilize a target field value to determine experiment values for the values in the multiple-variable equation, and then the laboratory confirmation experiment is conducted under conditions at the experiment values. The experiment values, as determined using the multiple-variable equation set to the target field value, produce laboratory conditions in the laboratory confirmation experiment of step 108 that simulate the field conditions the produce the target field value. In aspects, the success of the laboratory confirmation experiment can be confirmed by comparing the simulated field result value with the target field value. For example, for a successful laboratory confirmation experiment, the difference between the simulated field result value and the target field result value can be less than 10%, 9%, 8%, 7%, 6%, 5%, 4%, 3%, 2%, or 1%.

FIG. 2 illustrates a flowchart of an embodiment of the first step 102 in the method 100 of FIG. 1. That is, FIG. 2 illustrates that obtaining a multiple-variable equation for calculating a parameter using laboratory-measured data can include steps 202, 204, and 206.

At step 202, the method 100 can include conducting laboratory experiments where each of the laboratory experiments has variable values for the variables in the multiple-variable equation that are within a range that was previously determined for each of the variables. Each laboratory experiment has multiple variables, where each variable has a variable value that is within a previously determined range for the variable. The laboratory experiments are conducted in step 202 under the same procedure as the laboratory confirmation experiment in step 108. In aspects where asphaltene deposition is the parameter measured in the laboratory experiments, the laboratory experiments are conducted without presence of an asphaltene control chemical.

The method 100 then proceeds to step 204. At step 204, the method 100 can include measuring laboratory values for the parameter for the laboratory experiments. There is a laboratory value for the parameter for each laboratory experiment. Measuring laboratory values can be accomplished using any technique known for measuring the parameter. Standardized methods such as ASTM and ISO methods can be used, proprietary methods can be used, or custom laboratory measurement techniques can be used to measure the parameter. An example of measuring asphaltene deposition is described in part of the experiment procedures for the example disclosed herein.

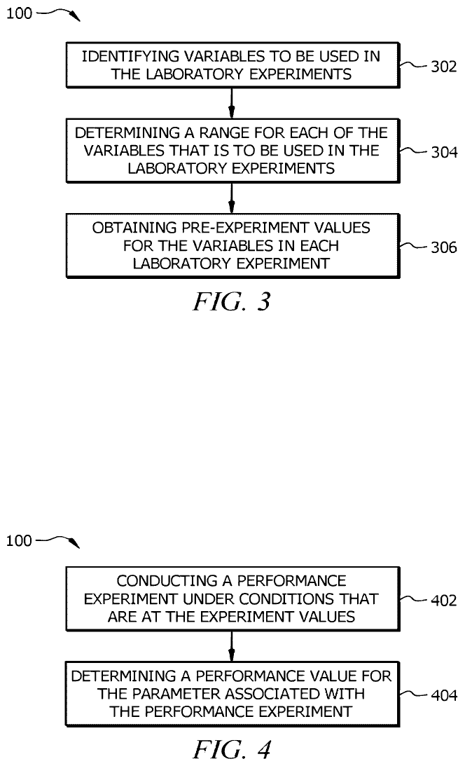

The method 100 then proceeds to step 206. At step 206, the method 100 can include determining the multiple-variable equation based on the laboratory values of the parameter measured for the laboratory experiments and the variable values for the laboratory experiments. It is noted that the multiple-variable equation is determined in step 206 after the experiments are conducted in step 202. Thus, experiments are conducted in step 202 to obtain laboratory values for the parameter based on multi-factor experimental design (such as via the technique described for the steps in FIG. 3) which are measured in step 204, and then the multiple-variable equation is determined based on the laboratory values and the variable values of the laboratory experiments. In aspects, a multi-variable experimental design software can be used to generate the multiple-variable equation.

In aspects, the multiple-variable equation has a regression value of greater than 95%, 96%, 97%, 98%, or 99%. In aspects, the step 206 of determining the multiple-variable equation can include performing a regression analysis for the parameter versus the laboratory values that are measured for the parameter. Examples of regression analysis include a linear, quadratic, and cubic regression.

In aspects of steps 202, 204, and 206, the laboratory experiments are conducted with a micro-reactor; the variables are two or more of a duration of experiment, a temperature in the micro-reactor, a heptane concentration in the micro-reactor, and a mixing rate in the micro-reactor; and the parameter is asphaltene deposition.

FIG. 3 illustrates a flowchart of additional steps in the disclosed method 100 that can be performed prior to step 202 (e.g., in aspects where step 102 includes step 202).

In step 302, the method 100 includes identifying the variables that are to be used in the laboratory experiments. The variables are identified as conditions that can be varied over a series of the laboratory experiments. In aspects, the number of variables in the multiple-variable equation can be in a range of from 2 to 15 variables; alternatively, 2 to 10 variables; alternatively, 2 to 5 variables. In some cases the number of variables is less than the number of conditions that could potentially be varied in laboratory experiments that determine or measure the parameter. For example, one might observe that for asphaltene deposition measured in Example 1 herein, three conditions out of four described conditions were chosen as variables for the parameter of asphaltene deposition (i.e., temperature in Example 1 was not selected as a variable and held constant for all laboratory experiments). In other cases, the number of variables can be equal to the number of conditions that could potentially be varied in laboratory experiments that determine or measure the parameter. The variables can be identified by a person; alternatively, the variables can be identified by a multi-factor experimental design software.

The method 100 then proceeds to step 304. In step 304, the method 100 includes determining the range for each of the variables that is to be used in the laboratory experiments. The range of heptane concentration can be based on the flocculation point analysis of the crude oil and can comprise a span of 5 to 20% v/v over this concentration. Mixing rate (RPM) can be somewhat based on the reservoir from where the crude oil is sourced, e.g., mixing rate can depend on whether the flow regime is in a transitional or turbulent regime. The time range for duration of experiment can be based on asphaltene content and flocculation point of the crude oil. The range for temperature (if included as a variable) can be based on the actual temperature of the reservoir. In aspects, the range for a variable can be specific numerical points, such as is used for heptane concentration in Example 1 herein. In such aspects, one of the specific numerical points is selected for the variable. In aspects, the ranges are entered in the multiple-variable experimental design software.

The method 100 the proceeds to step 306. In step 306, the method 100 includes obtaining pre-experiment values for the variables for each of the laboratory experiments. There is a pre-experiment value for each variable in each laboratory experiment. In aspects, the pre-experiment values obtained in step 306 are the variable values utilized in step 202. In aspects, the pre-experiment values are generated by the multi-variable experimental design software. In aspects, the pre-experiment values are obtained from the multi-variable experimental design software, which generates the pre-experiment values based on input for the identity of the variables and input for the range of values that can apply to each of the variables.

FIG. 4 illustrates a flowchart of additional steps in the disclosed method 100.

At step 402, the method 100 can include conducting a performance experiment under conditions that are at the experiment values for the variables in the multiple-variable equation. In aspects, the performance experiment is conducted according to the same procedure for which the laboratory experiments and laboratory confirmation experiment were conducted. Different than the laboratory confirmation experiment in step 108 and the laboratory experiments in step 202, the performance experiment in step 402 is conducted in presence of a product, condition, or process step that is to be tested and compared with the laboratory confirmation experiment and laboratory experiments which are conducted in the absence of the product, condition, or process step. Because of the presence of the product, condition, or process step, the experiment procedure for the performance experiment is the same as the procedure for the laboratory experiments and the laboratory confirmation experiment, except for any additional step or steps needed in the procedure to account for the presence of the product, condition, or process step. In aspects, the performance experiment is conducted in the presence of a chemical product. In aspects, the performance value is based on the presence of the chemical product in the performance experiment. In aspects, the chemical product is an asphaltene control chemical and the parameter is asphaltene deposition.

The method 100 then proceeds to step 404. At step 404, the method 100 includes measuring a performance value for the parameter associated with the performance experiment. In aspects, the performance value for the parameter can be measured according to the same laboratory measurement technique by which the laboratory values for the parameter were measured.

In aspects, steps 402 and 404 can be repeated for any number of product, condition, or process step, for comparison of the products, conditions, or process steps with one another.

Significantly, the amount of time to perform method 100 that includes steps 402 and 404 using experiment values in steps 402 and 404 is a fraction of the amount of time it takes to obtain the experiment values and use the experiment values in steps 402 and 404 with single-variable experimental design.

### EXAMPLES

The following examples are illustrative of a multi-factor experimental technique for laboratory-scale asphaltene deposition experiments that utilize a field asphaltene deposition value as the target field value to determine the experiment values for the conditions performed in a laboratory confirmation experiment and subsequent performance experiments.

### Example 1

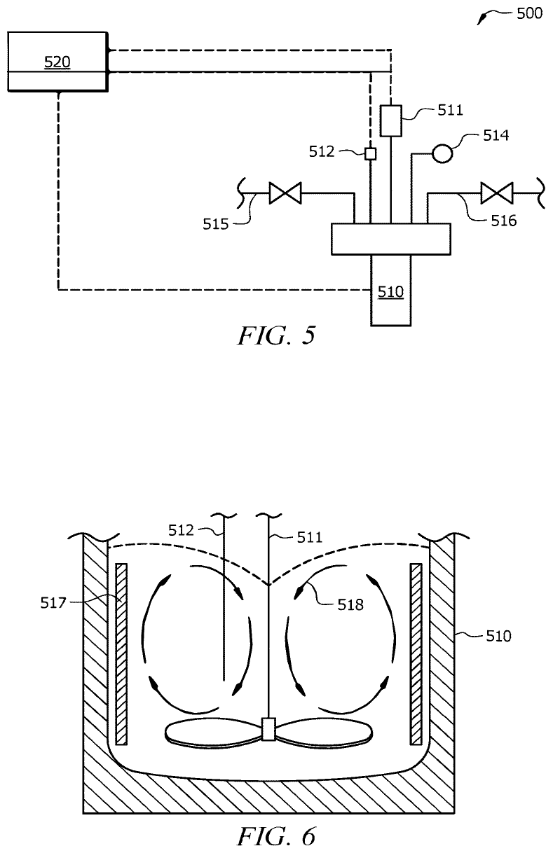

Laboratory experiments to determine asphaltene deposition (the parameter) were conducted using the apparatus 500 in FIG. 5. The apparatus included a Parr micro-reactor 510, an impeller 511, a thermocouple 512, a pressure gauge 514, a nitrogen supply conduit 515, a gas release conduit 516, and a controller 520 operatively connected to one or more of the Parr micro-reactor 510, the impeller 511, the thermocouple 512, and the pressure gauge 514.

A cross-sectional view of the micro-reactor 510 is illustrated in FIG. 6. Each of the impeller 511 and the thermocouple 512 extend into the interior of the micro-reactor 510. As can be seen, a metal mesh insert 517 is placed in the interior of the micro-reactor 510. Direction of fluid flow in the micro-reactor 510 is shown in direction of arrows 518. The fluid surface is indicated with dashed lines, in a contour that occurs while the impeller 511 mixes the fluid.

The variables used in laboratory experiments in the Parr micro-reactor were identified as duration of experiment, heptane concentration, and mixing rate. The range for duration of experiment was determined to be 30 minutes to 120 minutes, the range for heptane concentration was determined to be any value selected from 53.4 vol %, 61.6 vol %, and 68.3 vol %, and the range for mixing rate was determined to be 250 rpm to 450 rpm.

These variables were entered into a multi-factor experimental design software (Minitab Statistical Software), and the software was instructed to generate ten experiments having a pre-experiment value for each variable, where any value for duration of experiment was in a range of 30 minutes to 120 minutes, any value for heptane concentration selected from 53.4 vol %, 61.6 vol %, and 68.3 vol %, and any value for mixing rate was in a range of 250 rpm to 450 rpm. The heptane concentration was based on a total volume of materials in the Parr-micro reactor. It was decided to fix the temperature for the experiments at 84° C.; however, it is to be understood within the scope of this disclosure that temperature and any other variable can be included as variables input into the multi-factor experimental software for experimental conditions generation.

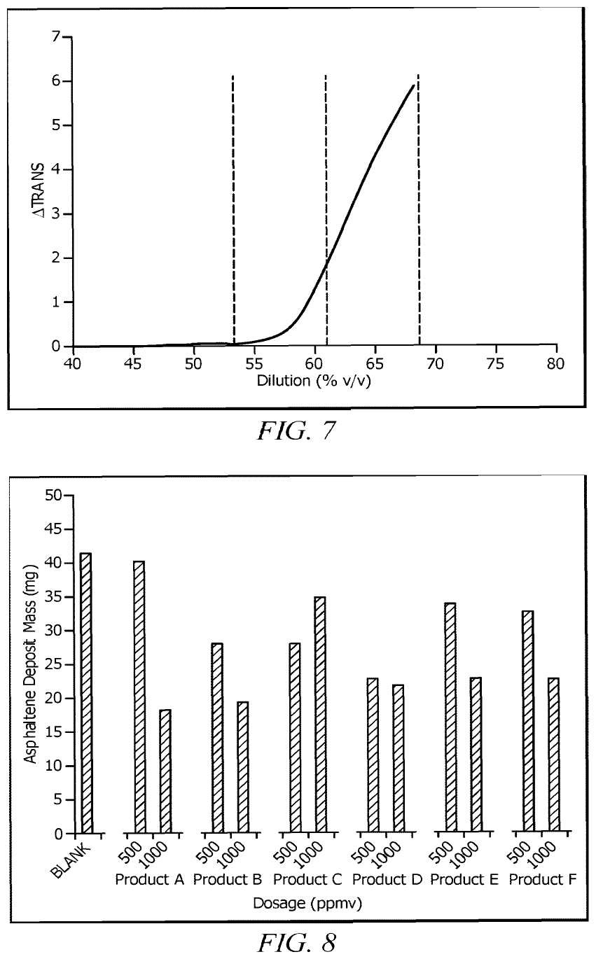

Heptane concentration could have been input as a range into the software, and the software could have selected values for heptane concentration within the range. However, in this Example 1, three specific values of 53.4 vol %, 61.6 vol %, and 68.3 vol % were input into the software. These values were obtained by a flocculation point analysis (FPA) of the crude oil, shown in FIG. 7.

The software was instructed to output ten combinations of pre-experiment values for the variables in the laboratory experiments, and the software output the following pre-experiment values in Table 1 below:

TABLE 1

| Laboratory | Pre-Experiment Values | | |
|---|---|---|---|
| Experiment | Duration of | Heptane | Mixing Rate |
| (#) | Experiment (min) | Concentration (vol %) | (RPM) |
| 1 | 30 | 68.3 | 250 |
| 2 | 120 | 53.4 | 450 |
| 3 | 120 | 53.4 | 250 |
| 4 | 60 | 61.6 | 350 |
| 5 | 120 | 68.3 | 250 |
| 6 | 30 | 68.3 | 450 |
| 7 | 70 | 53.4 | 450 |
| 8 | 60 | 61.6 | 350 |
| 9 | 30 | 53.4 | 250 |
| 10 | 120 | 68.3 | 450 |

Note that Laboratory Experiments 4 and 8 had the same conditions; thus, the closeness of the asphaltene deposition values (the parameter) subsequently obtained by conducting laboratory experiments at these conditions would be an indicator of reproducibility of the results.

Each of the Laboratory Experiments 1 to 10 was conducted with the pre-experiment values for the variables set as variable values for the variables, according to the following procedure with the apparatus 500 in FIG. 5 and FIG. 6:
1. Set the temperature and RPM to the desired set-point values on the controller 520.
2. Weigh metal mesh insert 517 (pre-cut 6 cm×10 cm by scissors or guillotine).
3. Carefully place mesh insert 517 into the reactor 10 ensuring a good fit, and using the mesh removal tool, place the mesh insert 517 at the bottom of the micro-reactor 510.
4. Weigh micro-reactor 510 with mesh insert 517 placed therein.
5. Transfer the appropriate volume of crude oil into the micro-reactor 510 using a dispensing syringe. The crude oil was the same for each experiment. The volume of crude oil for each experiment was calculated based on a total volume of the micro-reactor 510 being 50 mL and the heptane concentration that was generated for the respective experiment by the multi-factor experimental design software (e.g., in Experiment 1 the appropriate volume of crude oil was 50 ml−(50 ml*68.3 vol % heptane)=15.85 ml crude oil).
6. Add the appropriate volume of heptane to micro-reactor 510 using the dispensing syringe based on the generated value from the software for the respective experiment.
7. Weigh micro-reactor 510 with the insert, crude oil, heptane, and optional chemical product.
8. Attach the micro-reactor 510 to the Parr unit using the heating mantle as support and tighten bolts using wrench.
9. Close all valves (the valve in nitrogen supply conduit 515, and the valve in the gas relief conduit 516).
10. Move heating mantle into position and insert heater thermocouple.
11. Turn on impeller 511.
12. Open the valve in the nitrogen supply conduit 515 to flood the micro-reactor 510 with nitrogen, close the valve, check for leakage, and if no leakage is detected, then slowly degas the micro-reactor 510 by opening the valve in the gas relief conduit 516. Repeat two times. After repeating, close all valves.
13. Turn on heater and wait until the thermocouple 512 indicates that the temperature in the micro-reactor 510 reaches 84° C.
14. Start timer when the temperature of 84° C. is reached and prepare a water bath.
15. Once the duration of experiment time has elapsed, turn off heater and remove heater thermocouple and heating mantle. Submerge the micro-reactor 510 in the water bath and wait until the thermocouple 512 indicates that the temperature in the micro-reactor 510 has reached 64° C.
16. Dispose of water and slowly degas the system by opening the valve in the gas relief conduit 516.
17. Once the micro-reactor 510 is depressurized to atmospheric pressure, turn off the impeller 511.
18. Disassemble the micro-reactor 510 from the rest of the Parr equipment.
19. Weigh the micro-reactor 510.
20. Wash the Parr reactor internals (stirrer and thermocouple) with toluene.
21. Discard the reactor fluids and remove the mesh insert 517 with the mesh removal tool.
22. Place the mesh insert 517 in a wide mouth beaker and place the beaker having the mesh insert in an oven at 80° C.
23. Clean out reactor using toluene, and dry.
24. After 5 minutes, remove mesh insert 517 from oven and weigh.
25. Fill the wide mouth beaker with cyclohexane so it is half full.
26. Place the mesh insert 517 into the cyclohexane with 6 cm edges facing up (concave) and, using tweezers, gently move the mesh insert 517 from side to side for 20 seconds.
27. Place the mesh insert 517 in the 80° C. oven.
28. After 5 minutes, remove the mesh insert 517 and weigh the mesh insert 517.
29. Repeat step 25 through 28 using toluene.
30. Record all masses. The asphaltene deposition mass (mg) was the difference between the mass of the mesh insert 17 after cyclohexane wash and the mass of the mesh insert 17 after the toluene wash.

Table 2 below shows the laboratory values for the parameter (asphaltene deposition) measured from each of the Laboratory Experiments 1 to 10:

TABLE 2

| | Asphaltene | |
|---|---|---|
| Laboratory | Deposition | Asphaltene Deposition |
| Experiment | (mg asphaltenes/ | (wt %, mg asphaltenes deposited per |
| (#) | g oil) | mg asphaltenes in the crude oil) |
| 1 | 3.22 | 12.4 |
| 2 | 2.57 | 9.9 |
| 3 | 0.43 | 1.7 |
| 4 | 3.03 | 11.6 |
| 5 | 3.52 | 13.5 |
| 6 | 2.08 | 8.0 |
| 7 | 0.68 | 2.6 |
| 8 | 2.92 | 11.2 |
| 9 | 0.37 | 1.4 |
| 10 | 2.93 | 11.3 |

The laboratory values for asphaltene deposition of Experiments 4 and 8 demonstrate reproducibility for the laboratory experiments. For example, asphaltene deposition for Experiment 4 was 11.6 wt % (based on mg asphaltenes deposited per mg asphaltenes in the crude oil) and 3.03 mg asphaltenes/g oil. Asphaltene deposition for Experiment 8 was 11.2 wt % (based on mg asphaltenes deposited per mg asphaltenes in the crude oil) and 2.92 mg asphaltenes/g oil, which is about 3.6% difference, which is within error of 10% typically seen for asphaltene deposition tests.

A regression analysis was then performed for all the variable values in Experiments 1 to 10 for duration of experiment, heptane concentration, and mixing rate relative to the laboratory values measured for asphaltene deposition, to give a multiple-variable equation with variables for duration of experiment, heptane concentration, and mixing rate to calculate asphaltene deposition, where the regression of the equation was greater than 95%.

A target field value for asphaltene deposition of 8 wt % (based on mg asphaltenes deposited per mg asphaltenes in the crude oil), or 2.1 mg asphaltenes/g oil, was identified. The asphaltene deposition value for the multi-variable equation was then set to 2.1 mg asphaltenes/g oil, the target field value, and experiment values for duration of experiment, heptane concentration, and mixing rate were calculated from the multi-variable equation using the target field value. The experiment value for duration of experiment was found to be 30 minutes, the experiment value for heptane concentration was found to be 54.7 vol %, and the experiment value for mixing rate was found to be 450 rpm.

A laboratory confirmation experiment was then conducted with the same procedure and conditions as Laboratory Experiments 1 to 10, and with the same experiment values as Laboratory Experiments 1 to 10 for the variables: a duration of 30 minutes, a heptane concentration of 54.7 vol %, and a mixing rate of 450 rpm. The asphaltene deposition (the simulated field result value) for the laboratory confirmation experiment was reported to be 8.1±0.2% wt % (based on mg asphaltenes deposited per mg asphaltenes in the crude oil), or 2.1+/−0.2 mg asphaltenes/g oil, which is statistically the same as the target field value of 8 wt % (based on mg asphaltenes deposited per mg asphaltenes in the crude oil), or 2.1 mg asphaltenes/g oil. Thus, the calculated experiment values of the variables (duration of experiment, heptane concentration, and mixing rate) according to the disclosed multi-factor experimental design technique accurately generated a simulated field result value for asphaltene deposition that was statistically equal to the target field value for asphaltene deposition.

### Example 2

Various chemical products were tested for asphaltene control in performance experiments, where each chemical product was tested under the conditions that included the experiment values of the laboratory confirmation experiment in Example 1. The same procedure for Laboratory Experiments 1 to 10 in Example 1 was used for the performance experiments in Example 2, except the chemical product was added to the reactor 10 between steps 5 and 6 of the procedure.

Each chemical product was tested at a dosage of 500 ppmv and separately at a dosage of 1,000 ppmv, based on a total volume of crude oil and heptane in the reactor 10.

FIG. 8 is a bar graph of asphaltene deposit mass (the performance value) for several performance experiments. Asphaltene deposit mass is reported in units of (mg).

The first bar on the left in the graph is labeled “Blank”, which means that the micro-reactor contained no chemical product to test for asphaltene control. The Blank experiment set a baseline for asphaltene deposition mass from the crude oil. The remaining bars in the bar graph reflect asphaltene deposition mass values for performance experiments conducted for Product A at a dosage of 500 ppmv and 1,000 ppmv, Product B at a dosage of 500 ppmv and 1,000 ppmv, Product C at a dosage of 500 ppmv and 1,000 ppmv, Product D at a dosage of 500 ppmv and 1,000 ppmv, Product E at a dosage of 500 ppmv and 1,000 ppmv, and Product F at a dosage of 500 ppmv and 1,000 ppmv. Products A to F are anonymized herein for proprietary purposes.

Product A had a reduction in asphaltene deposit mass compared to the Blank of 3 wt % for a dosage of 500 ppmv and 56 wt % for a dosage of 1000 ppmv.

Product B had a reduction in asphaltene deposit mass compared to the Blank of 32 wt % for a dosage of 500 ppmv and 53 wt % for a dosage of 1000 ppmv.

Product C had a reduction in asphaltene deposit mass compared to the Blank of 33 wt % for a dosage of 500 ppmv and 16 wt % for a dosage of 1000 ppmv.

Product D had a reduction in asphaltene deposit mass compared to the Blank of 45 wt % for a dosage of 500 ppmv and 48 wt % for a dosage of 1000 ppmv.

Product E had a reduction in asphaltene deposit mass compared to the Blank of 19 wt % for a dosage of 500 ppmv and 46 wt % for a dosage of 1000 ppmv.

Product F had a reduction in asphaltene deposit mass compared to the Blank of 22 wt % for a dosage of 500 ppmv and 47 wt % for a dosage of 1000 ppmv.

FIG. 8 indicates that Product D is the best asphaltene control chemical for the performance experiments conducted at a dosage of 500 ppmv, having a reduction in deposit mass compared with the blank of 45 wt %. Product A is the best performer at a dosage of 1,000 ppmv.

Product E, which was not a traditional kinetic inhibitor, had positive performance.

An important aspect of the results illustrated in FIG. 8, is that the performance values for asphaltene deposition for the chemical products were obtained in one week using the multi-variable experimental design described herein to obtain the experiment values, by which all chemical products were tested in the performance experiments. A single-factor experimental design approach would have taken months to obtain the experiment values for testing the chemical products in the performance experiments.

### ADDITIONAL DESCRIPTION

Aspect 1. A method comprising: obtaining a multiple-variable equation containing a plurality of variables for calculating a parameter using laboratory-measured data; setting the multiple-variable equation equal to a target field value for the parameter; determining experiment values for the plurality of variables in the multiple-variable equation based on setting the multiple-variable equation equal to the target field value for the parameter; and conducting a laboratory confirmation experiment under conditions that are at the experiment values for the plurality of variables to obtain a simulated field result value for the parameter.

Aspect 2. The method of Aspect 1, wherein the laboratory confirmation experiment is conducted in a micro-reactor, wherein the plurality of variables are two or more of a duration of experiment, a temperature in the micro-reactor, a heptane concentration in the micro-reactor, and a mixing rate in the micro-reactor, wherein the parameter is asphaltene deposition.

Aspect 3. The method of Aspect 1 or 2, wherein the simulated field result value and the target field value are both in a range of from about 1 wt % to about 14 wt % asphaltene based on mass asphaltenes deposited per mass of asphaltenes in a crude oil.

Aspect 4. The method of any one of Aspects 1 to 3, wherein the plurality of variables is from 2 to 15 variables.

Aspect 5. The method of any one of Aspects 1 to 4, further comprising: conducting a plurality of laboratory experiments, wherein each of the plurality of laboratory experiments has variable values for the plurality of variables that are within a range determined for each of the plurality of variables; measuring laboratory values for the parameter for the plurality of laboratory experiments; and determining the multiple-variable equation based on the laboratory values of the parameter measured for the plurality of laboratory experiments and the variable values.

Aspect 6. The method of Aspect 5, wherein the multiple-variable equation has a regression value of greater than 95%.

Aspect 7. The method of Aspect 5 or 6, wherein determining the multiple-variable equation includes performing a regression analysis for the parameter versus the laboratory values that are measured for the parameter.

Aspect 8. The method of any one of Aspects 5 to 7, wherein each of the plurality of laboratory experiments is conducted with a micro-reactor, wherein the plurality of variables are two or more of a duration of experiment, a temperature in the micro-reactor, a heptane concentration in the micro-reactor, and a mixing rate in the micro-reactor, wherein the parameter is asphaltene deposition.

Aspect 9. The method of any one of Aspects 5 to 8, further comprising, prior to conducting the plurality of laboratory experiments: identifying the plurality of variables that are to be used in the plurality of laboratory experiments; determining the range for each of the plurality of variables that is to be used in the plurality of laboratory experiments; and obtaining pre-experiment values for the plurality of variables for each of the plurality of laboratory experiments.

Aspect 10. The method of Aspect 9, wherein the pre-experiment values are generated by a multiple-variable experimental design software.

Aspect 11. The method of Aspect 9 or 10, wherein the pre-experiment values are the variable values when conducting the plurality of laboratory experiments.

Aspect 12. The method of any one of Aspects 1 to 11, further comprising: conducting a performance experiment under the conditions that are at the experiment values for the plurality of variables; and measuring a performance value for the parameter associated with the performance experiment.

Aspect 13. The method of Aspect 12, wherein the performance experiment is conducted in a presence of a chemical product, wherein the performance value is based on the presence of the chemical product in the performance experiment.

Aspect 14. The method of Aspect 13, wherein the chemical product is an asphaltene control chemical, wherein the parameter is asphaltene deposition.

Aspect 15. The method of any one of Aspects 1 to 14, wherein the laboratory confirmation experiment is conducted without a presence of an asphaltene control chemical.

Aspect 16. The method of any one of Aspects 1 to 15, wherein the target field value is a known field value.

Aspect 17. The method of any one of Aspects 1 to 16, wherein the target field value is an average of a plurality of known field values.

Aspect 18. The method of any one of Aspects 1 to 17, further comprising: obtaining the target field value based on a known condition measurement of a commercial-scale process or product.

Aspect 19. The method of any one of Aspects 1 to 18, wherein the multiple-variable equation is obtained using multiple-variable experimental design software.

Aspect 20. The method of Aspect 19, wherein a first amount of time using the multiple-variable experimental design software to obtain the multiple-variable equation is less than a second amount of time using single-variable experimental design to obtain the multiple-variable equation.

Aspect 21. A computer having at least one processor and at least one memory containing instructions, that when executed by the at least one processor, cause the computer to: generate a multiple-variable equation containing a plurality of variables for calculating a parameter using laboratory-measured data; receive a target field value for the parameter via a first user input to the computer; set the multiple-variable equation equal to the target field value for the parameter; and determine experiment values for the plurality of variables in the multiple-variable equation based on setting the multiple-variable equation equal to the target field value for the parameter.

Aspect 22. The computer of Aspect 21, wherein the instructions further cause the computer to: receive a second user input comprising a number of the plurality of variables; receive a third user input comprising a range for each of the plurality of variables.

Aspect 23. The computer of Aspect 21 or 22, wherein the instructions further cause the computer to: receive a second user input comprising laboratory values of the parameter measured for a plurality of laboratory experiments and variable values (pre-experiment values) determined for the plurality of variables as disclosed herein, wherein the multiple-variable equation is generated based on the laboratory values of the parameter measured for the plurality of laboratory experiments and the variable values.

Aspect 24. A system comprising: the computer of any one of Aspects 21 to 23; and an apparatus configured to operate a laboratory confirmation experiment under conditions that are at the experiment values for the plurality of variables to obtain a simulated field result value for the parameter that can be measured from the laboratory confirmation experiment.

Aspect 25. An apparatus configured to operate a laboratory confirmation experiment under conditions that are at experiment values for a plurality of variables to obtain a simulated field result value for a parameter that can be measured from the laboratory confirmation experiment, wherein multiple-variable experimental design is used to determine a multiple-variable equation, wherein the experiment values are determined by setting the multiple-variable equation equal to a target field value.

Although the present disclosure and its advantages have been described in detail, it should be understood that various changes, substitutions and alterations can be made herein without departing from the spirit and scope of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A method comprising:
obtaining a multiple-variable equation containing a plurality of variables for calculating a parameter using laboratory-measured data;
setting the multiple-variable equation equal to a target field value for the parameter;
determining experiment values for the plurality of variables in the multiple-variable equation based on setting the multiple-variable equation equal to the target field value for the parameter; and
conducting a laboratory confirmation experiment under conditions that are at the experiment values for the plurality of variables to obtain a simulated field result value for the parameter.

2. The method of claim 1, wherein the laboratory confirmation experiment is conducted in a micro-reactor, wherein the plurality of variables are two or more of a duration of experiment, a temperature in the micro-reactor, a heptane concentration in the micro-reactor, and a mixing rate in the micro-reactor, wherein the parameter is asphaltene deposition.

3. The method of claim 1, wherein the simulated field result value and the target field value are both in a range of from about 1 wt % to about 14 wt % asphaltene based on mass asphaltenes deposited per mass of asphaltenes in a crude oil.

4. The method of claim 1, wherein the plurality of variables is from 2 to 15 variables.

5. The method of claim 1, further comprising:
conducting a plurality of laboratory experiments, wherein each of the plurality of laboratory experiments has variable values for the plurality of variables that are within a range determined for each of the plurality of variables;
measuring laboratory values for the parameter for the plurality of laboratory experiments; and
determining the multiple-variable equation based on the laboratory values of the parameter measured for the plurality of laboratory experiments and the variable values.

6. The method of claim 5, wherein the multiple-variable equation has a regression value of greater than 95%.

7. The method of claim 5, wherein determining the multiple-variable equation includes performing a regression analysis for the parameter versus the laboratory values that are measured for the parameter.

8. The method of claim 5, wherein each of the plurality of laboratory experiments is conducted with a micro-reactor, wherein the plurality of variables are two or more of a duration of experiment, a temperature in the micro-reactor, a heptane concentration in the micro-reactor, and a mixing rate in the micro-reactor, wherein the parameter is asphaltene deposition.

9. The method of claim 5, further comprising, prior to conducting the plurality of laboratory experiments:
identifying the plurality of variables that are to be used in the plurality of laboratory experiments;
determining the range for each of the plurality of variables that is to be used in the plurality of laboratory experiments; and
obtaining pre-experiment values for the plurality of variables for each of the plurality of laboratory experiments.

10. The method of claim 9, wherein the pre-experiment values are generated by a multiple-variable experimental design software.

11. The method of claim 9, wherein the pre-experiment values are the variable values when conducting the plurality of laboratory experiments.

12. The method of claim 1, further comprising:
conducting a performance experiment under the conditions that are at the experiment values for the plurality of variables; and
measuring a performance value for the parameter associated with the performance experiment.

13. The method of claim 12, wherein the performance experiment is conducted in a presence of a chemical product, wherein the performance value is based on the presence of the chemical product in the performance experiment.

14. The method of claim 13, wherein the chemical product is an asphaltene control chemical, wherein the parameter is asphaltene deposition.

15. The method of claim 1, wherein the laboratory confirmation experiment is conducted without a presence of an asphaltene control chemical.

16. The method of claim 1, wherein the target field value is a known field value or an average of a plurality of known field values.

17. The method of claim 1, further comprising:
obtaining the target field value based on a known condition measurement of a commercial-scale process or product.

18. The method of claim 1, wherein the multiple-variable equation is obtained using multiple-variable experimental design software, wherein a first amount of time using the multiple-variable experimental design software to obtain the multiple-variable equation is less than a second amount of time using single-variable experimental design to obtain the multiple-variable equation.

19. A computer having at least one processor and at least one memory containing instructions, that when executed by the at least one processor, cause the computer to:
generate a multiple-variable equation containing a plurality of variables for calculating a parameter using laboratory-measured data;
receive a target field value for the parameter via a first user input to the computer;
set the multiple-variable equation equal to the target field value for the parameter; and
determine experiment values for the plurality of variables in the multiple-variable equation based on setting the multiple-variable equation equal to the target field value for the parameter.

20. An apparatus configured to operate a laboratory confirmation experiment under conditions that are at experiment values for a plurality of variables to obtain a simulated field result value for a parameter that can be measured from the laboratory confirmation experiment, wherein multiple-variable experimental design is used to determine a multiple-variable equation, wherein the experiment values are determined by setting the multiple-variable equation equal to a target field value.
